(19) United States
(12) Patent Application Publication
(10) Pub. No.: US 2012/0014073 A1
(43) Pub. Date: Jan. 19, 2012

(54) CONDUCTIVE NANOPARTICLE SUBSTRATE AND METHOD OF MANUFACTURE

(75) Inventors: R. Douglas CARPENTER, Tustin, CA (US); Christopher William Winn, Corona, CA (US)

(73) Assignee: QUANTUMSPHERE, INC., Santa Ana, CA (US)

(21) Appl. No.: 13/243,863

(22) Filed: Sep. 23, 2011

Related U.S. Application Data
(63) Continuation of application No. 11/951,223, filed on Dec. 5, 2007, now abandoned.

(51) Int. Cl. H05K 7/00; H05K 1/09; B05D 3/02; B05D 5/12; B05D 5/00; B82Y 99/00; B82Y 30/00

(52) U.S. Cl. 361/748; 427/125; 174/257; 427/58; 977/773; 977/932

(57) ABSTRACT

A device comprising a substrate with first and second layers is prepared by applying a cellulosic base layer on the substrate followed by a silver nanoparticle coating. The nanoparticle coating is durable and highly electrically conductive. This conductive substrate maybe used for the application of integrated circuitry components, and does not outgas upon application of reflow solder.

### CROSS-REFERENCE TO RELATED APPLICATIONS

This application claims priority to U.S. patent application Ser. No. 11/951,223, filed Dec. 5, 2007, entitled CONDUCTIVE NANOPARTICLE SUBSTRATE AND METHOD OF MANUFACTURE, the entire contents of which are incorporated herein by this reference.

### BACKGROUND OF THE INVENTION

1. Technical Field

The inventions disclosed herein relate generally to electrically conductive metal coatings on substrates for the electronics and optics industries.

2. Related Art

On the market today there exist many conductive inks/pastes of metals such as silver or copper which can be coated onto glass to form an electrically conductive surface. These metal coated glass substrates are used in a variety of applications, in particular chips in many electronic components. While these commercial ink/paste adhesives have utility in certain applications, durability issues exist when used in applications such as integrated circuits.

Firstly, commercially available ink or paste adhesives cannot be used in applications that require a sealed environment and further processing which involves heat. The epoxy in these commercially available adhesive outgases when heated, which can result in pressure build up and catastrophic failure of a chip. Secondly, because these commercial ink/paste adhesives use larger silver particles, the resulting silver layer is less even and more prone to surface defects and conductivity gaps. Furthermore, the conductive surface must be adherent and robust enough to permit solder reflow for the attachment of circuitry components.

### SUMMARY OF THE INVENTION

In the preferred embodiments, a device is described which comprises a substrate with an electrically conductive surface having first and second layers. The first layer comprises cellulosic material and the second layer comprises silver nanoparticles. The substrate comprises a material that is available to react with cellulosic material, for example a silicate material such as glass. Alternatively, polyimide, an acrylic, or a metal may also function as the substrate.

In some of the preferred embodiments, nitrocellulose is utilized as the first layer on the substrate. When nitrocellulose is heated, nitrogen is off-gassed such that a thin film of cellulose remains. This film may chemically interact with the substrate such that the film is not easily removed by scratching or with adhesive. The first layer serves as a contact substrate for the silver nanoparticles.

In other preferred embodiments, the device may serve as the primary support of an integrated circuit. Electronic components such as resistors and capacitors may be soldered directly to the device without destruction of the first and second layers. Additionally, the second layer does not contain a solvent which may potentially outgas and destroy the integrity of the circuit.

Some of the preferred embodiments describe a method of preparing an electrically conductive device. Nitrocellulose is dissolved into a solvent such as acetone and applied to a clean substrate surface, such as glass. After drying at about 50° C. to eliminate solvent and heating to about 225° C. to eliminate nitrogen, a thin layer of cellulose remains. The cellulose layer is highly adherent to the substrate. A dispersion of about 25 wt % silver nanoparticles in ethylene glycol or other volatile solvent may then be applied to the surface and heated at about 250° C. to form an electrically conductive surface that is highly adherent to the primary layer.

In other aspects of the preferred embodiments, the primary layer may be formed using other cellulosic materials other than nitrocellulose. In addition, these cellulosic materials may be dissolved in other volatile solvents. This may increase or decrease the temperature required for the heating and drying steps of the primary layer. Also, the dispersion of conductive nanoparticles used in the method of preparing the device is not limited to about 25 wt % silver in ethylene glycol. For example, copper nanoparticles compatabilized in a different solvent may also form the conductive second layer.

### BRIEF DESCRIPTION OF THE DRAWINGS

FIG. 1 is a schematic of the electrically conductive device, comprising a substrate, first, and second layer.

### DETAILED DESCRIPTION

The inventive device described herein comprises an electrically conductive substrate for the fabrication of integrated circuitry, having a substrate, first, and second layers. This device should have specific qualities that permit the reflow of solder across the surface for the attachment of electrical components, namely high electrical conductivity, good adhesion, scratch resistance. Additionally, the device should not off-gas solvent during or after the placement of electrical components, as this may lead to non-uniformity of the conductive surface and ultimate failure of the circuit.

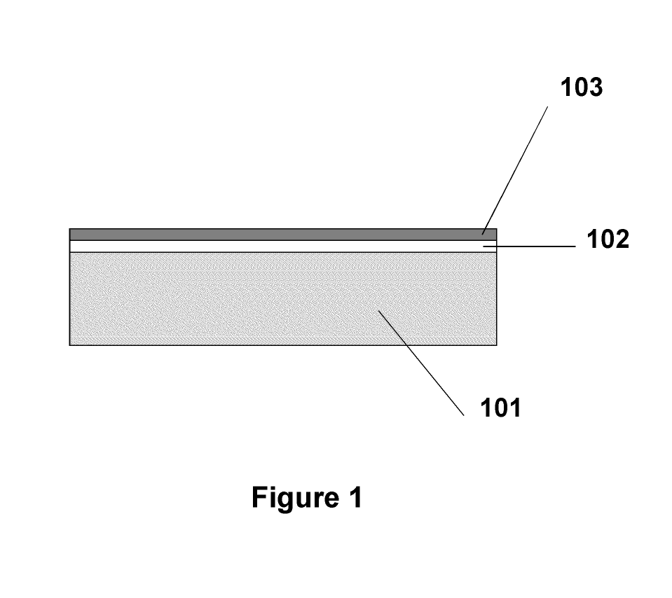

Referring to FIG. 1, device substrate 101 is comprised of a material which can chemically interact with cellulose-based primary layer 102 upon which a secondary layer of silver 103 is applied. Substrate materials may be but are not limited to glass, polyimide, acrylic, or a metal. For example, when nitrocellulose is dissolved in a solvent such as acetone, a thin film may be cast on the substrate. Upon heating, the nitrocellulose chemically condenses and eliminates nitrogen. The resulting cellulose material may then chemically bond to the substrate.

After the first layer is established, functional groups on the cellulose can chemically bind to silver nanoparticles, thus forming good chemical and physical contact. Because the silver particles are nano-sized, a more uniform layer is formed during the sintering process. Silver nanoparticles may be dispersed in a solvent, such as ethylene glycol and directly applied to the first layer. Upon heating to remove the solvent, the resulting silver layer is uniform, conducting, and adherent. Solvents that have a boiling point below 225° C. are preferred, such that all of the solvent can be eliminated at low temperature heating. Due to the sensitivity of many substrates, heating of the device during fabrication should not exceed 300° C.

We experienced significant difficulty in providing good adhesion between the substrate and the silver nanoparticles, especially if the particles have a high melting point or do not have affinity for the substrate. Silver nanoparticles do not contain oxide material, which limits their direct bonding to a substrate such as glass. If a dispersion of silver nanoparticles are directly applied to glass and then heated, the resulting layer is conductive but is easily removed by scratching or tape test. To achieve our goal of a robust, high conductivity device that does not off-gas after preparation, a new method was invented to overcome this challenge.

The method used herein describes a dual-layer approach to promote adhesion of nanoparticles to a substrate to form a durable device for integrated circuitry. In this method, a base layer of nitrocellulose is applied to the glass. Upon heating, the nitrocellulose gives off nitrogen gas to form a thin film of cellulose. The functionalities on the cellulose bind well to glass. After this layer is established, other end groups on the cellulose film can chemically interact to the silver nanoparticles, thus forming good chemical and physical contact. Because the silver particles are nano-sized, a more uniform layer is formed during the sintering process.

In the first step, the substrate is cleaned well with acetone to remove any residual dust or other impurities. The solvents used in this method must be carefully selected such that they do not leave residues on the substrate and are removed at temperatures below 225° C. A solution of nitrocellulose in acetone is then cast onto the surface of the substrate. To ensure that all of the acetone is removed from the film, a first heating step at 50° C. for one hour is used. This is then followed by a heating step at 225° C. to remove nitrogen and chemically bond cellulose to glass. Next, a dispersion of silver nanoparticles is cast onto the first layer. Nanoparticles referenced herein have high electrical conductivity. Although larger sizes are contemplated, the metal nanoparticles desirably have a diameter of less than 100 nm. The smaller the nanoparticles size, the more likely they are to efficiently provide a uniform layer on surfaces. Metal nanoparticles may be produced by a variety of methods. One such method is detailed in U.S. Pat. No. 7,282,167, Ser. No. 10/840,409, which is incorporated herein in its entirety by reference.

In another aspect of the invention, the silver nanoparticles are then heated to 250° C. to both remove the solvent and sinter the metal particles. A heating process is commonly used in known sintering techniques. For example, if the silver nanoparticles and are heated to cause grain growth, the particles combine to form larger particles. One of ordinary skill in the art should recognize that any sintering process is likely to produce some grain growth and, thus, it is anticipated that the resulting electrodes will include grains that have grown larger than the original silver particles, including grain sizes that are larger than “nano-scale”.

Alternative solvents and nanoparticles may be used in the described method. For example, other conductive metal nanoparticles such as copper, nickel, iron, and cobalt will also provide significant electrical contact and adhere well to the substrate and first layers. Other solvents that evaporate at relatively low temperatures such as water, and many alcohols, aldehydes, ketones, ethers, and esters may also serve as dispersion solvents for the nanoparticles.

The foregoing description is that of preferred embodiments having certain features, aspects, and advantages in accordance with the present inventions. Various changes and modifications also may be made to the above-described embodiments without departing from the spirit and scope of the inventions.

### EXAMPLE 1

### Preparation of Aconductive Substrate

A glass surface was cleaned with acetone and allowed to dry. About 1 gram of nitrocellulose was dissolved in acetone, and the resulting solution was coated onto the glass. This coating was dried at 50° C. for one hour followed by a second heating at 225° C. for 30 minutes. Finally, the substrate plus cellulose coating was coated with a 25 wt % solution of silver nanoparticles in ethylene glycol. The resulting layer was dried at 250° C. for 30 minutes to remove residual ethylene glycol.

What is claimed is:

1. An electrically conductive device comprising a substrate and an electrically conductive surface comprising first and second layers, the first layer comprising cellulosic material and the second layer comprising silver nanoparticles.

2. The device of claim 1, wherein the substrate comprises functional groups available to react with the cellulosic material.

3. The device of claim 1, wherein the substrate comprises a silicate material.

4. The device of claim 3, wherein the silicate material comprises glass.

5. The device of claim 1, wherein the substrate comprises one from a group of either a polyimide, an acrylic, or a metal.

6. The device of claim 1, wherein the device comprises an integrated circuit.

7. The device of claim 1, wherein the first layer comprises nitrocellulose material heated to form a thin layer of cellulose.

8. A method of preparing an electrically conductive device, the method comprising:
dissolving nitrocellulose in acetone,
cleaning a glass surface with acetone and allowing the surface to dry, and
coating the glass with a layer of the nitrocellulose/acetone solution.

9. The method of claim 8, further comprising drying the resulting coating at about 50° C. for about 1 hour and then at about 225° C. for about 30 minutes.

10. The method of claim 9, further comprising applying a 25% by wt solution of silver nanoparticles in ethylene glycol to the coating, and heated the device at about 250° C. for about 30 minutes.

11. A method of preparing an electrically conductive device, the method comprising:
dissolving a cellulosic material in a solvent,
cleaning a surface of a substrate,
coating the substrate with a layer of the cellulosic solution,
drying the resulting coating at an elevated temperature,
applying a solution of metal nanoparticles to the coating, and
further heating the device at an elevated temperature.

12. The method of claim 11, wherein the substrate comprises glass.

13. The method of claim 11, wherein the cellulosic material is nitrocellulose.
